(19) United States
(12) Patent Application Publication
(10) Pub. No.: US 2022/0077362 A1
(43) Pub. Date: Mar. 10, 2022

(54) Component Having Homogenized Luminous Surface

(71) Applicant: OSRAM Opto Semiconductors GmbH, Regensburg (DE)

(72) Inventors: Peter Nagel, Regensburg (DE); Christopher Wiesmann, Barbing (DE); Matthias Kiessling, Bad Abbach (DE)

(21) Appl. No.: 17/433,060

(22) PCT Filed: Feb. 7, 2020
(86) PCT No.: PCT/EP2020/053165

§ 371 Date: Aug. 23, 2021

(30) Foreign Application Priority Data
Feb. 27, 2019 (DE) 10 2019 104 978.4

(51) Int. Cl. H01L 33/58; H01L 25/075; H01L 33/50

(52) U.S. Cl. CPC H01L 33/58; H01L 2933/0091; H01L 33/50; H01L 25/0753

(57) ABSTRACT

In an embodiment a component includes a common carrier, a plurality of component parts, converter layers and internal scattering regions, wherein the component parts are arranged side by side in a lateral direction and vertically between the common carrier and the converter layers, wherein the component has a pass-through region and a radiation exit surface which, in a vertical direction, is spaced apart from the converter layers by the pass-through region, wherein adjacent converter layers are laterally spaced from each other by an intermediate region which, in top view of the carrier, is completely covered by the pass-through region, and wherein the inner scattering regions adjoin the pass-through region and the converter layers and are arranged at least partially in the intermediate region or directly adjoin the intermediate region.

This patent application is a national phase filing under section 371 of PCT/EP2020/053165, filed Feb. 7, 2020, which claims the priority of German patent application 102019104978.4, filed Feb. 27, 2019, each of which is incorporated herein by reference in its entirety.

### TECHNICAL FIELD

A component, in particular an optoelectronic component having a plurality of component parts, is specified which has a particularly homogenized luminous surface.

### BACKGROUND

Between two or more light-emitting component parts, there is often a dark region which is not illuminated brightly enough by the component parts. The presence of this dark region is due to the fact that the component parts, especially the light-emitting semiconductor chips, cannot be placed arbitrarily close to each other due to manufacturing tolerances or due to the risk of short circuits. In addition, due to possible encapsulation, the component parts often have a luminous surface that is smaller than the chip size. Thus, the component is limited in some applications, especially in direct lens projections, due to both a brightness difference and a non-negligible color difference between different regions on the luminous surface of the component. Compensation of the dark regions between the light-emitting component parts, for example by external optical devices, proves to be complex and cost-intensive.

### SUMMARY

Embodiments provide a compact, low-cost component that can be produced in a simplified manner and has a homogenized luminous surface.

According to at least one embodiment of the component, it has a plurality of component parts arranged side by side on a common carrier. In particular, the common carrier has a mounting surface which faces the component parts and comprises a plurality of connection surfaces for electrically contacting the component parts. In particular, the common carrier is formed as a printed circuit board having a base body, electrical connection surfaces and electrical tracks. For example, the component parts are arranged in rows and columns on the mounting surface. The component may have at least two, three, four, five, or at least ten rows and/or columns of the component parts.

According to at least one embodiment, the component has a plurality of converter layers. For example, a converter layer is assigned, in particular uniquely assigned, to each component part. The converter layer is configured, for example, to convert short-wave, for example ultraviolet or blue radiation components of the electromagnetic radiation generated by the underlying component part during operation of the component into long-wave, for example yellow, green or red radiation components. For example, the converter layer contains radiation-active phosphors. For example, the converter layer is a ceramic platelet having phosphors embedded therein.

Each component part can be formed by a single semiconductor chip. In this case, a converter layer can be uniquely assigned to each semiconductor chip. In particular, in lateral directions, the converter layer can be flush with its associated component part or fully surround the semiconductor chip. It is also possible for the component part to comprise a plurality of semiconductor chips, wherein in top view, the semiconductor chips of the same component part are covered by the same contiguous converter layer. In a plane view of the common carrier, the converter layer may completely cover its associated semiconductor chips. It is possible for the converter layer to completely enclose its associated semiconductor chips in lateral directions. The converter layer may be in the form of a converter platelet which is manufactured separately from the semiconductor chip and attached to the semiconductor chip. Alternatively, it is possible that during the production, the converter layer is applied directly to the semiconductor chip or to the component part. It is also conceivable that the converter layer is formed as an envelope, which in top view covers and in lateral directions encloses the component part, the semiconductor chip or the semiconductor chips.

A lateral direction is understood to be a direction that runs along, in particular parallel to, the mounting surface of the common carrier. A vertical direction is understood to be a direction that is transverse or perpendicular to the mounting surface. The vertical direction and the lateral direction are thus transverse or perpendicular to each other.

According to at least one embodiment of the component, it has inner scattering regions which are configured to homogenize a luminous surface of the component. The inner scattering regions are preferably formed in those areas of the component wherein inhomogeneities, for example with regard to brightness, luminosity or color values, would occur.

The inner scattering regions can be formed as empty cavities, which are arranged in particular at lateral edges of the converter layer, of the component part or of the semiconductor chip. The cavities may be filled with a material that differs from the materials of the layers surrounding the cavities, for example in terms of refractive index and/or radiation transmission. For example, the cavities are filled with an adhesion promoter material or with a matrix material, in which for instance radiation scattering and/or radiation reflecting particles are embedded. It is also possible that the cavities are filled with air, for instance with ambient air. Furthermore, the scattering properties of the inner scattering regions can be adjusted in a targeted manner by suitable geometric shapes of the cavities. For example, the cavities have inner walls that are concave and/or convex in shape, at least in places.

According to at least one embodiment of the component, it has a pass-through region. The pass-through region is in particular the vertical region between the converter layers and a radiation exit surface of the component. The radiation exit surface of the component may be formed by an exposed surface of the pass-through region. In top view of the common carrier, the pass-through region may completely cover all converter layers and all component parts.

The pass-through region may be in the form of an independent prefabricated and radiation-transmissive body, which is arranged on the converter layers and attached to them, for example, by an adhesion promoter layer. The pass-through region may be in the form of a platelet. For example, the pass-through region is a glass or sapphire body. It is possible that the pass-through region is formed from a ceramic material or from a radiation-transmissive, in particular from a transparent composite material for instance siloxane, silicone and epoxy, or from composites of castable materials comprising ceramics, or consists of one of these materials.

In contrast to an independent prefabricated body, which is attached to the converter layers by means of a connection layer, for example, the pass-through region can be arranged directly on the converter layers. For example, the pass-through region is part of a mold body, in particular an integrated part of a mold body formed in one piece, which is applied to the converter layers and the component parts and/or around the converter layers and the component parts, for example by a molding process. In this case, all the component parts and/or all the converter layers can be fully enclosed by the mold body in all lateral directions. The mold body has a centrally arranged partial area which, in top view, covers all converter layers and, in particular, forms the pass-through region.

A molding process is generally understood to mean a process by which a casting material is shaped and cured, preferably under the impact of pressure, to form the mold body. In particular, the term “molding process” includes molding, film assisted molding, injection molding, transfer molding and compression molding.

In at least one embodiment of a component comprising a common carrier, a plurality of component parts, converter layers, and internal scattering regions, the component parts are arranged adjacent to each other in the lateral direction and between the common carrier and the converter layers in the vertical direction. The component has a pass-through region and a radiation exit surface, wherein the radiation exit surface is spaced from the converter layers in the vertical direction by the pass-through region. Adjacent converter layers are laterally spaced from each other by an intermediate region which, in top view of the carrier, is completely covered by the pass-through region. The inner scattering regions are adjacent to the pass-through region as well as to the converter layers, wherein the inner scattering regions are at least partially disposed in the intermediate region or are directly adjacent to the intermediate region.

The pass-through region increases the optical path available for the light emitted by the component parts and/or converted by the converter layers to propagate and mix before being coupled out from the component. The optical path is given by the product of the vertical layer thickness and the refractive index of the pass-through region. Due to the increased optical path, on the one hand, the probability of light spreading over different emission angles across the radiation exit surface, i.e. across the luminous surface, increases, and light can fill out a previously dark-appearing gap between adjacent converter layers or component parts. On the other hand, radiation of different colors is better mixed, so that a high color rendering index is achieved. If, in addition, internal scattering regions are located in the immediate vicinity of the gap or the intermediate region between the converter layers, the above-mentioned effects with regard to light distribution and light mixing are additionally enhanced, as a result of which a particularly homogeneous and, in particular, white-appearing luminous surface can be achieved during operation of the component.

According to at least one embodiment of the component, the component parts and/or the converter layers are arranged in row/s and/or column/s on the mounting surface of the common carrier. The component may have a plurality of intermediate regions between the adjacent component parts and/or converter layers. Some intermediate regions, in particular all intermediate regions, may be connected to each other. The intermediate regions may form an interconnected network, wherein the component parts and/or the converter layers, which are not arranged at the edges, may be enclosed by the intermediate regions in all lateral directions. For the sake of clarity, the component is described with one intermediate region or with one contiguous intermediate region. However, the features disclosed in connection with the one intermediate region can be used for all intermediate regions.

According to at least one embodiment of the component, the inner scattering regions, the converter layers and the pass-through region have different material compositions. In other words, the converter layers have a first material composition which does not occur for instance in the scattering regions and in the pass-through region. In addition, the pass-through region may be formed from a material that is different from a material of the scattering regions and different from a material of the converter layer. Due to the different material compositions, the component may have a refractive index jump at an interface between the pass-through region and the scattering regions or at an interface between the scattering regions and the converter layers, respectively. Depending on the geometry of the interface and the size of the refractive index jump, the light impinging on the interface can be partially scattered and/or reflected.

According to at least one embodiment of the component, the intermediate region is at least partially filled with a separating layer. The separating layer may contain radiation scattering and/or radiation reflecting particles. Such particles may be titanium oxide particles embedded in a matrix material of the separating layer. The internal scattering regions are arranged in a vertical direction, for example, between the separating layer and the pass-through region. In particular, the material composition of the scattering regions is different from the material composition of the separating layer. In other words, the separating layer and the inner scattering regions are different subregions of the component formed from different materials.

According to at least one embodiment of the component, the separating layer is diffuse-reflective. In lateral directions, the separating layer can fully enclose the component parts. This does not necessarily mean that all component parts are fully enclosed by the separating layer. In particular, the component parts arranged at the edges are only partially enclosed by the separating layer. In the vertical direction, the separating layer may partially fill the intermediate region or the intermediate regions. In particular, along the vertical direction, the separating layer extends from the mounting surface of the carrier to the inner scattering region or regions.

According to at least one embodiment of the component, the radiation exit surface is parallel to the mounting surface of the common carrier. The radiation exit surface is parallel to the mounting surface of the carrier if the radiation exit surface has a global main extension plane that is parallel to the mounting surface. In this case, the radiation exit surface can be flat or have local out-coupling structures. The local out-coupling structures may be formed by structuring the radiation exit surface to increase the out-coupling efficiency of the component. The out-coupling structures are, for example, local elevations or depressions in nanometer or micrometer range.

According to at least one embodiment of the component, the scattering regions are in the form of fillets in the intermediate region. In particular, the fillets are filled with an adhesion promoter material, which is configured, for example, for attaching the pass-through region to the converter layers.

For example, the component has a connection layer that fixes the pass-through region to the converter layers. The connection layer is, for example, an adhesive layer. The fillets filled with the adhesion promoter material, in particular with an adhesive material, may be referred to as adhesive fillets. The connection layer adjoins for instance directly to the pass-through region and to the converter layers. The inner scattering regions and the connection layer may be formed from the same material. For example, the inner scattering regions and the connection layer form a common layer of the component, which in particular is formed in one piece. In top view of the carrier, the connection layer may completely cover the converter layers and the component parts. The connection layer is preferably radiation-transmissive, in particular transparent. It is possible for scattering particles to be embedded in the connection layer.

A fillet is generally understood to be a rounding of an edge or a corner, for instance the rounding of an edge or a corner of the intermediate region. In particular, it is a concave rounding. The rounding may face away from the pass-through region. In particular, the rounding faces the common carrier. If a separating layer or a mold body directly adjoins the concave rounding of the scattering region, the separating layer or mold body has a convex surface facing the scattering region.

According to at least one embodiment of the component, the pass-through region is formed by a prefabricated radiation-transmissive and self-supporting body. The prefabricated body is arranged on the converter layers and is spatially spaced from the common carrier. In other words, the prefabricated body and the common carrier do not have a common interface. The prefabricated body is also not part of a larger body which is adjacent or directly adjacent to the common carrier. The pass-through region is formed by the prefabricated body when the pass-through region is produced in a separate process and is subsequently attached to the converter layers. For example, the radiation-transmissive body is attached to the converter layers by an adhesive layer and/or by adhesive fillets. The scattering regions can be filled by materials of the adhesive layer or be formed as adhesive fillets.

According to at least one embodiment of the component, the scattering regions are in the form of incisions formed as recesses in the pass-through region. The incisions can be regarded as angular or round indentations of the pass-through region. Due to the indentations, the pass-through region may have a reduced vertical layer thickness at the intermediate regions. The indentations may be filled with air or with a solid material that is different from the material of the pass-through region and/or of the converter layers.

According to at least one embodiment of the component, the pass-through region is in the form of a platelet. The platelet may be a radiation-transmissive body. For example, the pass-through region has a constant vertical layer thickness. The radiation transmissive body has a lateral extent that is greater, for instance at least two times, four times, six times, or at least ten times greater than a vertical extent of the pass-through region. The pass-through region has a rear side facing away from the radiation exit surface, wherein the radiation exit surface is formed by a front side of the pass-through region facing away from the converter layers. In particular, the rear side and the front side of the pass-through region extend parallel to each other. For example, the front side of the pass-through region is at least partially or completely exposed.

The pass-through region has opposite side surfaces which are directed for instance perpendicular to the mounting surface of the carrier and run parallel to one another. It is possible that the pass-through region is formed, for example, by a radiation-transmissive body with inclined side surfaces. For example, the pass-through region has cross-sections that increase steadily with increasing distance from the converter layers. Compared to the opposite rear side of the pass-through region, the front side or the radiation exit surface has a smaller area in this case. In lateral directions, the pass-through region may project beyond the converter layers, in particular beyond all converter layers. However, it is possible for the pass-through region to be flush with the converter layers arranged at the edges in at least one lateral direction or in all lateral directions.

According to at least one embodiment of the component, the pass-through region and the component parts are enclosed, for example fully enclosed, in lateral directions by a mold body. The mold body can be formed as a housing of the component, which preferably directly adjoins the component parts and the pass-through region, as a result of which a mechanical attachment of the pass-through region to the converter layers and/or to the component parts is additionally reinforced. In particular, the radiation exit surface is free of a material of the mold body. For example, along the vertical direction, the mold body may be flush with the pass-through region or with the radiation exit surface. However, it is possible for the mold body to extend beyond the pass-through region along the vertical direction, or vice versa. The mold body may be arranged directly on the common carrier.

The mold body and the pass-through region can be formed from different materials. In particular, the mold body may contain radiation scattering and/or radiation reflecting particles. For example, the mold body is formed from a matrix material, for instance from a casting material, in which such particles are embedded. In a vertical direction and in lateral directions, outer surfaces of the component can be formed in places by surfaces of the mold body.

According to at least one embodiment of the component, the front side of the pass-through region is partially covered by a cover layer. The cover layer is in particular opaque to radiation, for example reflective or diffuse-reflective. The not covered areas of the front face form, for example, the radiation exit surface of the component. In top view, the radiation exit surface in this case may have a contour that differs from an outline of the front side of the pass-through region or of the component. By selectively covering the front side of the pass-through region with the cover layer, pictogram-like structures can be implemented on the radiation exit surface for targeted applications of the component. For example, the component is configured to be used as a light source in a headlight, for instance a low beam. In this case, the radiation exit surface may have the contour of a field hockey stick or similar contours. The cover layer and the mold body may be formed from the same material or from different materials.

According to at least one embodiment of the component, the pass-through region is formed as integral part of the mold body. In top view of the common carrier, in this case, the mold body can completely cover the component parts. In lateral directions, the mold body encloses the component parts in particular completely. The mold body can be directly adjacent to the inner scattering regions and/or to the converter layers.

If the pass-through region is formed as part of the mold body, the front side of the pass-through region can be curved, for example convexly curved. Alternatively, it is possible for the mold body to be flattened at least in the region of the pass-through region in such a way that the front side of the pass-through region is flat, i.e. substantially flat except for the out-coupling structures. The mold body can have an outer surface facing away from the common carrier, which is curved in some areas and flat in others.

According to at least one embodiment of the component, the common carrier is configured for mechanically stabilizing the component and at the same time for electrically contacting the component parts. The component parts can each have a rear side which faces the common carrier and comprises electrical connection points, wherein the component parts are electrically conductively connected to the common carrier in particular exclusively via their rear sides.

The component parts may each be formed as flip chips or semiconductor chips having through-vias, or may comprise a plurality of flip chips or of semiconductor chips having through-vias. Such semiconductor chip generally has a first semiconductor layer of a first charge carrier type, a second semiconductor layer of a second charge carrier type, and an active layer located therebetween, wherein the active layer is configured to generate radiation. For electrically contacting the second semiconductor layer, the through-via extends, for example, throughout the first semiconductor layer and the active layer into the second semiconductor layer, wherein the through-via can be externally electrically connected via the rear side of the semiconductor chip.

### BRIEF DESCRIPTION OF THE DRAWINGS

Further advantages, preferred embodiments of the component are apparent from the embodiments explained below in connection with FIGS. 1A to 5:

FIGS. 1A, 1B, 1C, and 1D show schematic representations of comparative examples of a component in top view or in sectional view;

FIGS. 1E, 2A, 2B, 2C, 2D, 2E, 2F, 3A and 3B show schematic representations of some exemplary embodiments of a component in plan or sectional view;

FIGS. 4A, 4B, 4C, 4D, 4E, and 4F show various exemplary embodiments illustrating some of the advantages of the components described here; and

FIG. 5 shows schematic representation of a further exemplary embodiment of a component in top view and partly in sectional view.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

### DETAILED DESCRIPTION OF ILLUSTRATIVE EMBODIMENTS

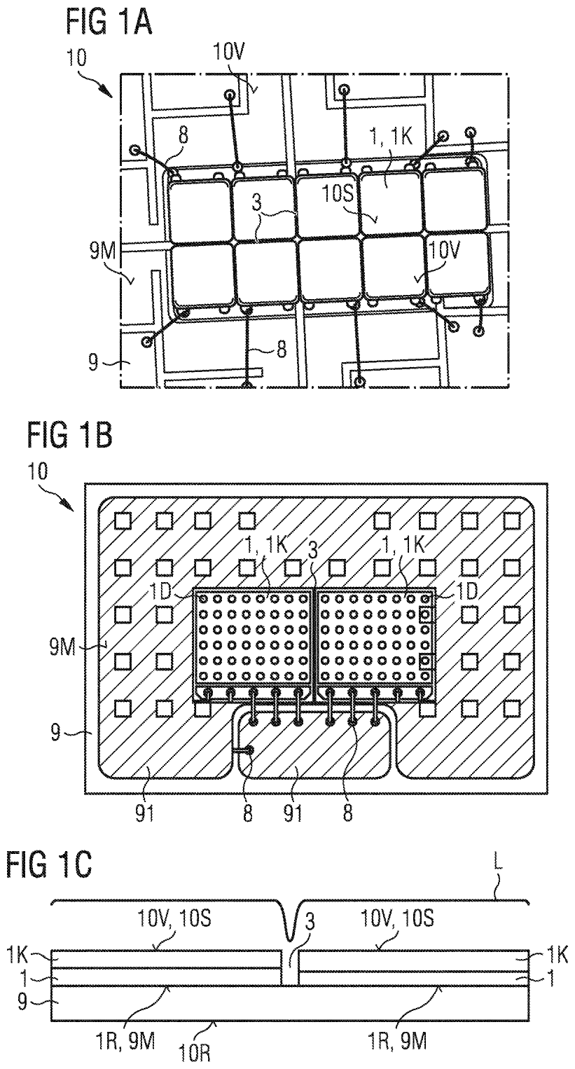

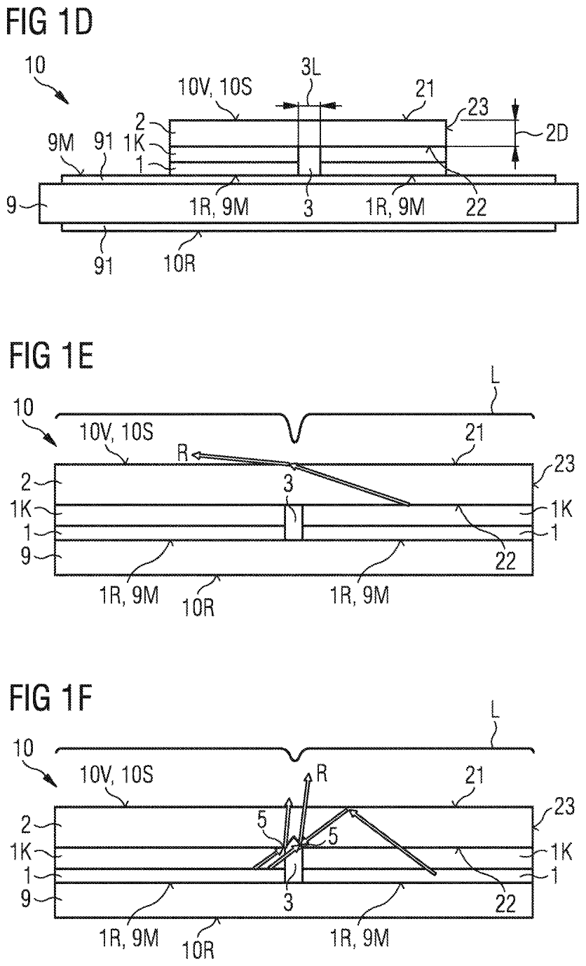

FIG. 1A shows a comparative example of a component 10 having a plurality of component parts 1 on a common carrier 9, wherein the component parts 1 are arranged in two rows of five component parts 1 each on a mounting surface 9M of the common carrier 9.

The mounting surface 9M has, in particular, connection surfaces 91 and/or electrical tracks (FIG. 1B). The component parts 1 can be arranged on different connection surfaces 91 and electrically conductively connected to them. Different connection surfaces 91 can also be electrically conductively connected to each other by electrical connections 8, so that the component parts 1 are connected in series or parallel to each other, for example.

Each component part 1 can be electrically connected to the connection surfaces 91 exclusively via its rear side 1R facing the mounting surface 9M. For electrical contacting of the component part 1 via the rear side 1R, the component part 1 may have at least one through-via 1D or several through-vias 1D. The component part 1 may be formed of a single semiconductor chip, for instance of a single light-emitting diode, or of a plurality of semiconductor chips, for instance of a plurality of light-emitting diodes. Each semiconductor chip of the component may have at least one through-via 1D or a plurality of through-vias 1D. If the component part 1 or the semiconductor chip is electrically contacted exclusively via its rear side 1R, the front side of the component part 1 or of the semiconductor chip may be free of electrical contact structures that could lead to local shading of the component 10.

The common carrier 9 may have an electrically insulating base body made, for example, of ceramic, plastic or a synthetic material. On one surface or on two opposing surfaces of the base body, the connection surfaces 91 and/or the electrical conductive tracks can be made of an electrically conductive material, for instance copper (FIG. 1D).

The common carrier 9 has a lateral extent which may be between 1 mm and 50 mm inclusive, for example between 1 mm and 20 mm inclusive or between 1 mm and 10 mm inclusive. The component part 1 has a lateral extent that is, for example, between 0.1 mm and 5 mm inclusive, for example between 0.1 mm and 2 mm inclusive or between 0.1 mm and 1 mm inclusive.

A converter layer 1K is uniquely assigned to each component part 1, wherein adjacent converter layers 1K are spatially spaced from one another in the lateral direction by an intermediate region 3 or by intermediate region regions 3.

The component 10 has a front side boy and a rear side 10R facing away from the front side boy. The rear side 10R is formed in particular by a surface of the common carrier 9. The front side boy may be formed in regions by the mounting surface 9M and in regions by surfaces of the converter layers 1K.

The component 10 has a radiation exit surface 10S on the front side boy. In particular, the radiation exit surface 10S is the portion of the front side boy that is illuminated during operation of the component 10. If the radiation exit surface 10S is substantially formed by the surfaces of the converter layers 1K, the radiation exit surface 10S often has dark intermediate regions 3 between the adjacent converter layers 1K during operation of the component 10. A luminosity distribution L describing the relative brightness of the radiation exit surface 10S is schematically shown in FIG. 1C in connection with a sectional view of the component 10 described, for example, in FIG. 1A or 1B. In addition to the reduced luminosity L, large deviations with respect to the color values occur in the intermediate regions 3 compared to the other regions of the radiation exit surface 10S.

The exemplary embodiment of a component 10 shown in FIG. 1D is essentially the same as the exemplary embodiment shown in FIG. 1C. In contrast, the component 10 has a radiation-transmissive pass-through region 2 with a vertical layer thickness 2D. The pass-through region 2 has a front side 21 facing away from the converter layers 1K, a rear side 22 facing the converter layers 1K, and side surfaces 23, wherein the front side 21 of the pass-through region 2 in particular forms the radiation exit surface 10S. For example, the pass-through region 2 is a prefabricated glass or sapphire body fixed on the converter layers 1K.

Due to the presence of the pass-through region 2, the optical path for the radiation R emitted by the component part 1 and/or converted by the converter layers 1K is enlarged before the radiation R is coupled out from the component 10. The emitted radiation R and the converted radiation R are thus better mixed and also partially reach the intermediate regions 3 before they are coupled out from the component 10 as mixed, in particular white, light at the front side 21 of the pass-through region 2.

The intermediate region 3 has a lateral extent 3L. Depending on the lateral extent 3L, the vertical layer thickness 2D of the pass-through region 2 can be adjusted in such a way that the luminous intensity distribution L is as homogenized as possible over the entire radiation exit area 10S, i.e. also in the intermediate regions 3.

For example, the pass-through region has a vertical layer thickness 2D which is, for example, between 300 μm and 5 mm inclusive, for instance between 500 μm and 5 mm inclusive, between 1 mm and 5 mm inclusive, or between 500 μm and 3 mm inclusive. In particular, a lateral distance 3L of adjacent converter layers is given by a lateral extent of the intermediate region 3 which is, for example, between inclusive 50 μm and 3 mm, approximately between inclusive 100 μm and 3 mm, between inclusive 500 μm and 3 mm, or inclusive 1 mm and 3 mm. To achieve the best possible light mixing, a ratio of the vertical layer thickness 2D of the pass-through region 2 to the lateral extent 3L of the intermediate region 3 is preferably between inclusive 0.5 and 10, for instance between inclusive 0.5 and 5, between inclusive 1 and 5, or inclusive 2 and 5, inclusive.

It is possible that side edge/s of the pass-through region 2, which is/are formed as a transparent window, is/are overprinted with highly filled TiO2 silicone or is lithographically patterned. This results in more design freedom, which in turn enables increased precision in the arrangement of the semiconductor chips and the converter layers.

The exemplary embodiment of a component 10 shown in FIG. 1E is substantially the same as the exemplary embodiment shown in FIG. 1C, but with the pass-through region 2. In a top view of the common carrier 1, the intermediate region 3 is completely covered by the pass-through region 2. In particular, the pass-through region 2 completely covers all the converter layers 1K and all the intermediate regions 3 between the adjacent converter layers 1K. Compared to the component 10 shown in FIG. 1C, the presence of the pass-through region 2 already result in a significant improvement in the luminous intensity distribution L outside and inside the intermediate regions 3.

The exemplary embodiment of a component 10 shown in FIG. 1F essentially corresponds to the exemplary embodiment shown in FIG. 1E. In contrast, the component 10 has inner scattering regions 5 within the intermediate regions 3 or in the immediate vicinity of the intermediate regions 3. In particular, the inner scattering regions 5 are adjacent to the pass-through region 2 as well as to the converter layers 1K. The inner scattering regions 5 may be arranged at least partially or completely in the intermediate region 3 or in the intermediate regions 3. Alternatively or additionally, the inner scattering regions 5 may be directly adjacent to the intermediate region 3 or to the intermediate regions 3.

According to FIG. 1F, the inner scattering regions 5 may be in the form of incisions in the pass-through region 2, wherein the incisions are directly adjacent to the intermediate region 3. The incisions may be depressions, indentations or notches on the rear side 22 of the pass-through region 2. The scattering regions 5 may be filled with a matrix material in which scattering particles are embedded. Compared to the component 10 shown in FIG. 1E, the inner scattering regions 5 lead to an additional homogenization of the luminous intensity distribution L on the entire radiation exit surface 10S.

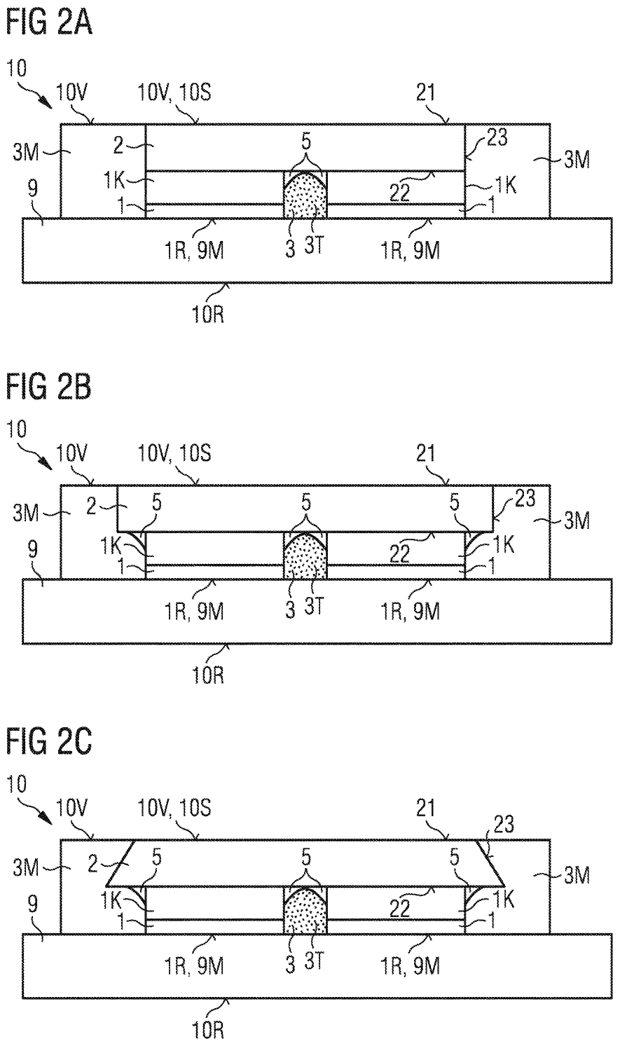

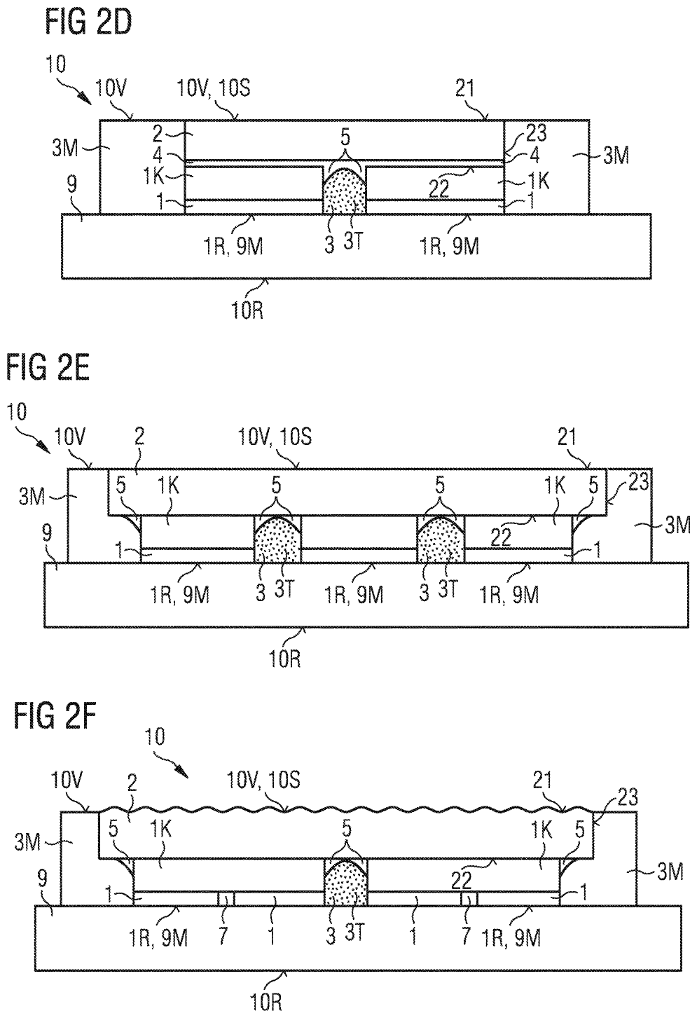

The exemplary embodiment of a component 10 shown in FIG. 2A essentially corresponds to the exemplary embodiment shown in FIG. 1F. In contrast thereto, the inner scattering regions 5 are formed as cavities in the intermediate region 3, which are filled with an adhesion promoter material, for example. In particular, the inner scattering regions 5 are formed as adhesive fillets, i.e. are formed as fillets filled with the adhesion promoter material, for example with an adhesive material. In particular, the adhesive fillets are directly adjacent to the converter layers 1K and directly adjacent to the pass-through region 2 and thus form a mechanical attachment of the pass-through region 2 to the converter layers 1K.

According to FIG. 2A, the component 10 has a separating layer 3T arranged in the intermediate region 3, wherein the inner scattering regions 5 are located in the vertical direction between the separating layer 3T and the pass-through region 2. Thus, the separating layer 3T only partially fills the intermediate region 3. The separating layer 3T may contain radiation-scattering and/or radiation-reflecting particles, for instance TiO2 particles, embedded in a matrix material made of, for example, silicone.

If the component 10 has a plurality of component parts 1 arranged in rows and columns, the separating layer 3T can completely enclose at least the centrally arranged component parts 1 in the lateral direction. The intermediate region 3 or intermediate regions 3 may be completely filled by the separating layer 3T together with the inner scattering regions 5. In particular, the material composition of the scattering regions 5 is different from the material composition of the separating layer 3T. In FIG. 2A, the separating layer 3T has a convex-shaped surface facing the pass-through region 2. The inner scattering regions 5, which are formed in particular as adhesive fillets, are directly adjacent to the separating layer 3T and have concave-shaped surfaces.

As a further difference to the component 10 shown in FIG. 1F, the component 10 according to FIG. 2A has a mold body 3M which is arranged on the common carrier 9 and completely encloses the arrangement of the component parts 1, the converter layers 1K and the pass-through region 2 in lateral directions. The mold body 3M thus forms a housing of the component 10, which in particular is directly adjacent to the component parts 1, to the converter layers 1K and to the pass-through region 2. This can ensure sufficient mechanical attachment of the pass-through region 2 to the converter layers 1K and/or to the component parts 1. The mold body 3M may be formed of a casting material. In particular, the mold body 3M may comprise reflective particles, for example TiO2 particles.

According to FIG. 2A, the mold body 3M is flush with the pass-through region 2 in the vertical direction. The front side boy of the component 10 may be formed in regions by the exposed surface of the mold body 3M and in regions by the exposed front side 21 of the pass-through region 2, wherein only the exposed front side 21 of the pass-through region forms the radiation exit surface 10S of the component 10. The radiation exit surface 10S is in particular free of a material of the mold body 3M.

The exemplary embodiment of a component 10 shown in FIG. 2B essentially corresponds to the exemplary embodiment shown in FIG. 2A. According to FIG. 2A, the pass-through region 2 closes in at least one lateral direction or in all lateral directions with the converter layers 1K and/or component parts 1 arranged at the edges. In contrast to this, the pass-through region 2 according to FIG. 2B projects laterally beyond the converter layers 1K arranged on the edge side. The pass-through region 2 and the converter layers 1K arranged at the edges form a step, in particular a surrounding step, or several steps along the vertical direction. The step or steps thus form an anchoring structure that prevents the mold body 3M from detaching from the assembly of the component parts 1, the converter layers 1K and the pass-through region 2.

Not only in the intermediate region 3 but also at a corner of the step or at the corners of the steps, inner scattering regions 5 are formed, which are formed in particular as adhesive fillets. The pass-through region 2 and the converter layers 1K are thus additionally attached to the mold body 3M.

The embodiment of a component 10 shown in FIG. 2C is substantially the same as the embodiment shown in FIG. 2B. According to FIG. 2B, the pass-through region 2 has side surfaces 23 that are substantially perpendicular to the mounting surface 9M. In contrast, the side surfaces 23 in FIG. 2C are oblique to the mounting surface 9M. As the vertical distance from the converter layers 1K increases, the cross-section of the pass-through region 2 decreases. The anchoring of the pass-through region 2 to the mold body 3M is thus additionally strengthened, which particularly increases the mechanical stability of the component 10.

The exemplary embodiment of a component 10 shown in FIG. 2D essentially corresponds to the exemplary embodiment shown in FIG. 2A. In contrast, it is explicitly shown in FIG. 2D that a connection layer 4, in particular an adhesive layer, is arranged in the vertical direction between the pass-through region 2 and the converter layers 1K. In top view, the connection layer 4 may completely cover the converter layers 1K, in particular all converter layers 1K. In particular, the connection layer 4 is radiation-transmissive. The connection layer 4 and the inner scattering regions 5 may be formed from the same material or from different materials.

It is also conceivable that the component 10 is free of such a connection layer 4, which is arranged between the pass-through region 2 and the converter layers 1K. For example, the pass-through region 2 can be temporarily fixed to the converter layers 1K, for example by of the inner scattering regions 5 formed as adhesive fillets, before the assembly of the component parts 1, the converter layers 1K and the pass-through region 2 is molded to form the mold body 3M.

The exemplary embodiment of a component 10 shown in FIG. 2E essentially corresponds to the exemplary embodiment shown in FIG. 2B, with the difference that according to FIG. 2E at least three rows or at least three columns of the component parts 1 or of the converter layers 1K are arranged on the common carrier. The component 10 can have any number of rows and columns of the component parts 1, so that the radiation exit surface can have any geometry. The centrally arranged component parts 1 and/or converter layers 1K may be fully surrounded by the separating layer 3T in the lateral direction.

The exemplary embodiment of a component 10 shown in FIG. 2F essentially corresponds to the exemplary embodiment shown in FIG. 2B, with the difference that the radiation exit surface 10S according to FIG. 2F is formed in a structured manner. The radiation exit surface 10S may have a plurality of out-coupling structures in the form of elevations or recesses. In all other exemplary embodiments, the radiation exit surface 10S may also have a structured design. In addition, FIG. 2F schematically shows that the component parts 1 may each have a plurality of semiconductor chips, for example in the form of light-emitting diodes. A common converter layer 1K is uniquely assigned to the semiconductor chips of the same component part 1.

In the lateral direction, the semiconductor chips of the same component part 1 can be spatially separated from each other by a separation trench 7 or by a plurality of separation trenches. It is also conceivable that the component part 1 is formed as a pixelated semiconductor chip that has a plurality of semiconductor bodies that are at least partially or completely separated from one another by a plurality of separation trenches 7. It is possible that the component part 1 comprises individually drivable semiconductor chips, semiconductor bodies or segments. A component 10 with such component parts 1 may find application in so-called DMD-LED (Digital Mirror Device-LED).

Deviating from FIGS. 2A to 2F, it is possible for the component 10 to have converter layers 1K that are smaller than the associated underlying component parts 1. Blue light emitted from the component parts 1 that does not directly impinge on the converter layers 1K can be scattered and spread out in the inner scattering regions 5. The so-called “blue-piping” effect can be used to increase the efficiency of the component 10. In particular, the blue light can be mixed together with excess amount of yellow light to form the white light.

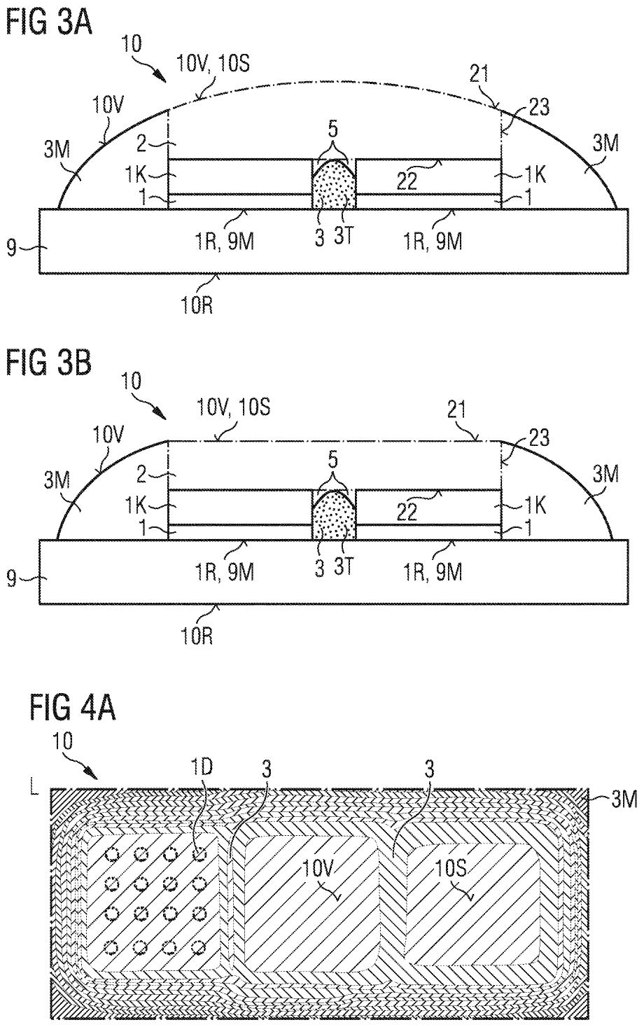

The exemplary embodiment of a component 10 shown in FIG. 3A essentially corresponds to the exemplary embodiment shown in FIG. 2A, with the difference that the pass-through region 2 is implemented as part of the mold body 3M. The mold body 3M comprising the pass-through region 2 can be applied directly to the converter layer 1K. A molding process is suitable for this purpose. For example, the assembly of the component parts 1 and the converter layers 1K is molded directly with a casting material, for instance silicone, after the separating layer 3T and the inner scattering regions 5 are formed. In top view of the common carrier 9, the mold body 3M completely covers all component parts 1, all converter layers 1K, the separating layer 3T and the inner scattering regions 5.

The example embodiment of a component 10 shown in FIG. 3B is substantially the same as the example embodiment shown in FIG. 3A. Referring to FIG. 3A, the component 10 has a convexly curved radiation exit surface 10S. In contrast, the radiation exit surface 10S is flat at least in the regions of the converter layers 1K except for possible local out-coupling structures.

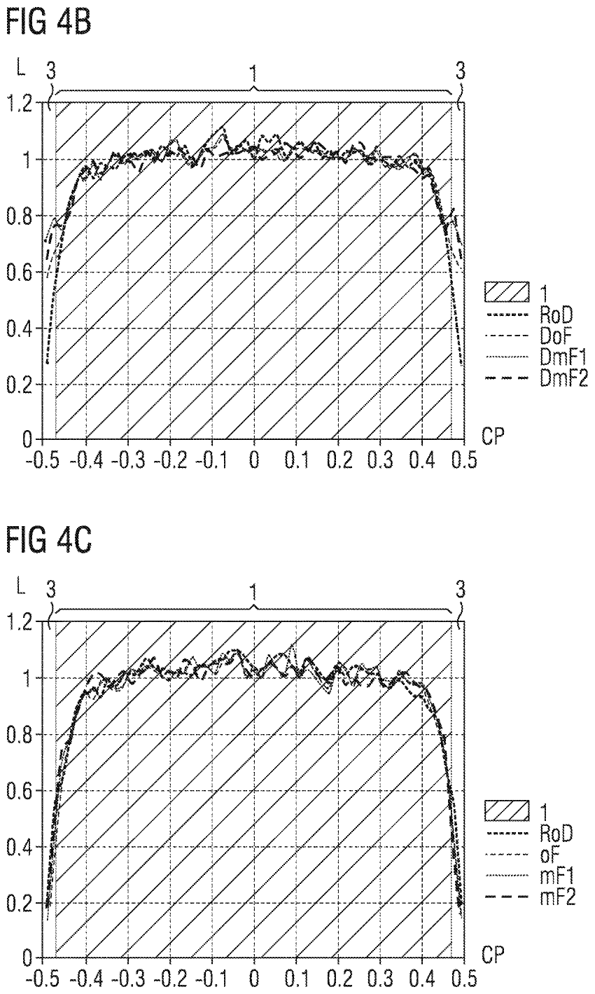

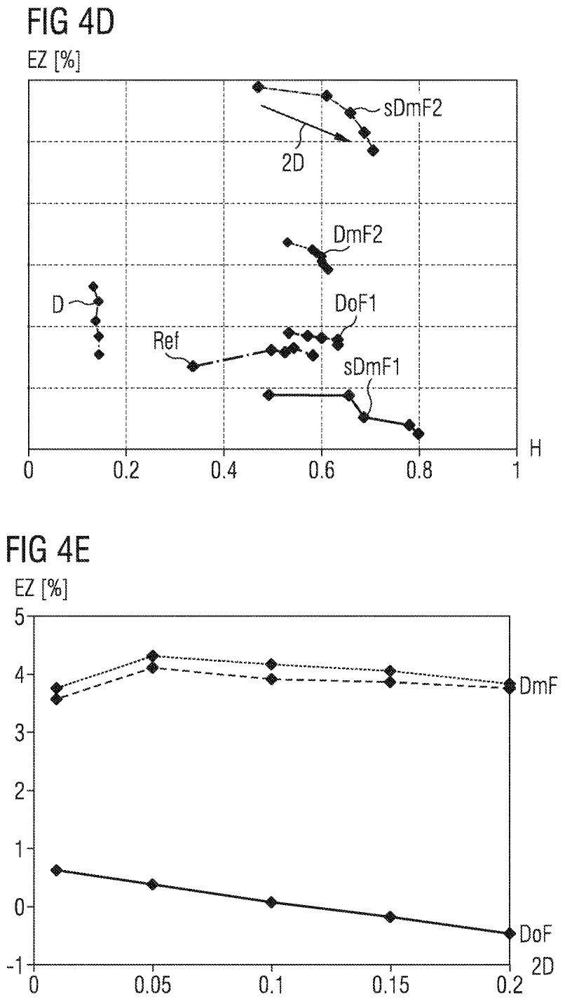

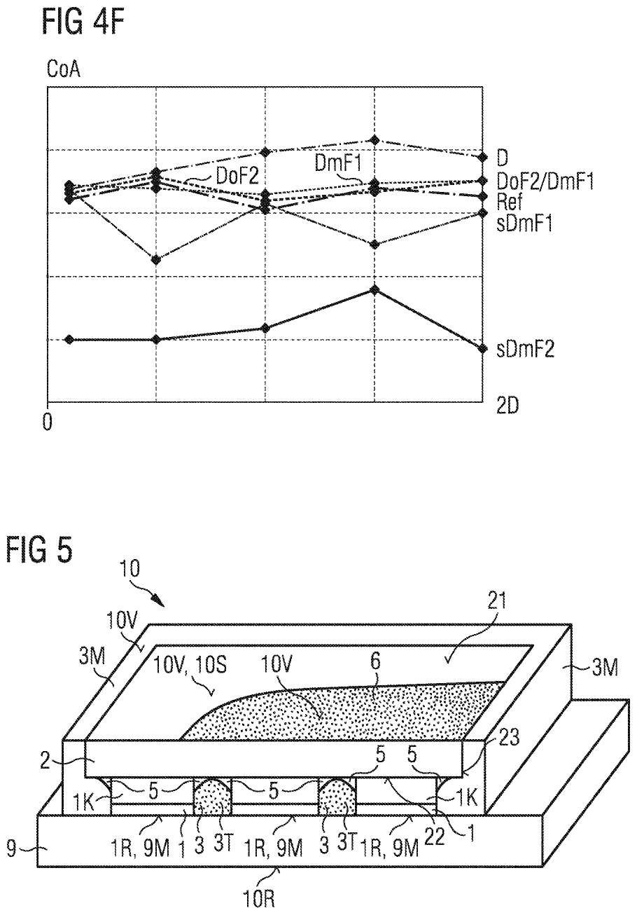

In FIG. 4A, the front side boy comprising the radiation exit surface 10S is schematically shown during operation of the component 10. Experiments have shown that the light intensity and light color are particularly evenly distributed over the entire radiation exit surface 10S due to the internal scattering regions 5. Also, the so-called yellow shift over the through-vias 1D essentially no longer appears.

FIGS. 4B and 4C show the relative luminous intensity distribution L across the position of the semiconductor chip or component part CP in the presence of a sapphire or glass pass-through region 2 (FIG. 4B) and in the absence of such a pass-through region (FIG. 4C), wherein the following abbreviations are used in the figures:

RoD=reference without pass-through region;

DoF=with sapphire pass-through region without adhesive fillets;

DmF1=with sapphire pass-through region and adhesive fillets;

DmF2=with pass-through region made of glass and with adhesive fillets;

oF=comparison curve for DoF/without homogenization;

mF1=comparison curve for DmF1/without homogenization; and

mF2=comparison curve for DmF2/without homogenization.

As can be clearly seen in 4B, the use of a pass-through region 2 already leads to a significant increase in the relative luminous intensity L in the intermediate regions 3 even in the absence of the adhesive fillets (cf. the curves RoD and DoF). In the presence of the adhesive fillets, the relative luminous intensity L is increased by a few more percentages, and the relative luminous intensity L in the intermediate regions 3 can reach values between 65% and 80%.

FIG. 4D shows the efficiency gain EZ and the degree of homogeneity H for different tests. The points on the same curve show, from left to right, the efficiency gain EZ and the degree of homogeneity H for different layer thicknesses 2D of the pass-through region 2. The following additional abbreviations are used in FIG. 4D:

D=with pass-through region made of glass;

Ref=reference curve of a general component with several component parts;

DoF1=with sapphire pass-through region without adhesive fillets;

sDmF1=with structured sapphire pass-through region and adhesive fillets; and

sDmF2=with structured pass-through region made of glass and with adhesive fillets.

As shown in FIG. 4D, the efficiency of the component and the degree of homogeneity H of the luminous intensity distribution decrease in the presence of the pass-through region of a comparatively thicker pass-through region 2.

FIG. 4E schematically shows the efficiency gain EZ as a function of the layer thickness 2D of the pass-through region. Tests have shown that the efficiency gain EZ can be about 4% when using the pass-through region 2 together with the inner scattering regions 5 (curve DmF).

FIG. 4F shows the color value differences for various embodiments of the component 10 as a function of the layer thickness 2D of the pass-through region 2. Tests have shown that the differences in the color value distribution (Color-over-Angle) are particularly small for a component 10 with a structured pass-through region 2 made of glass and with internal scattering regions 5, which are formed as adhesive fillets.

The exemplary embodiment of a component 10 shown in FIG. 5 essentially corresponds to the exemplary embodiment shown in FIG. 2E. In contrast, the component 10 has a cover layer 6 that partially covers the front side boy and, in particular, the radiation exit surface 10S. The covering layer 6 may be opaque to radiation, for instance reflective to radiation. Due to the partial covering, a light guiding can be achieved. The radiation exit surface 10S can thus be adapted to the functions of the component 10 in a targeted manner. In FIG. 5, the radiation exit surface 10S has the shape of a field hockey stick. The component 10 can be used as a light source for low beam in headlights.

The cover layer 6 thus serves as optical waveguide, since the design of the cover layer 6 determines the geometry of the radiation exit surface 10S. For example, a component 10 having a 3:2 ratio with the cover layer 6 can be changed to a component 10 having a 4:3 or 16:9 ratio only with minor losses, since the mold body 3M, the mounting surface 9M, and the cover layer 6 may be formed to be radiation-reflective, and the reflected light may possibly be coupled out from the component 10 after multiple reflections at the uncovered radiation exit surface 10S.

The invention is not restricted to the exemplary embodiments by the description of the invention made with reference to exemplary embodiments. The invention rather comprises any novel feature and any combination of features, including in particular any combination of features in the claims, even if this feature or this combination is not itself explicitly indicated in the claims or exemplary embodiments.

1-16. (canceled)

17. A component comprising:
a common carrier;
a plurality of component parts;
converter layers; and
internal scattering regions,
wherein the component parts are arranged side by side in a lateral direction and vertically between the common carrier and the converter layers,
wherein the component has a pass-through region and a radiation exit surface which, in a vertical direction, is spaced apart from the converter layers by the pass-through region,
wherein adjacent converter layers are laterally spaced from each other by an intermediate region which, in top view of the carrier, is completely covered by the pass-through region, and
wherein the inner scattering regions adjoin the pass-through region and the converter layers and are arranged at least partially in the intermediate region or directly adjoin the intermediate region.

18. The component according to claim 17, wherein the inner scattering regions, the converter layers and the pass-through region have different material compositions.

19. The component according to claim 17,
wherein the intermediate region is at least partially filled with a separating layer containing radiation-scattering and/or radiation-reflecting particles,
wherein the inner scattering regions are arranged in the vertical direction between the separating layer and the pass-through region, and
wherein a material composition of the scattering regions differs from a material composition of the separating layer.

20. The component according to claim 19, wherein the separating layer is diffuse-reflective and fully encloses the component parts in lateral directions.

21. The component according to claim 17, wherein the radiation exit surface is parallel to a mounting surface of the common carrier.

22. The component according to claim 17, wherein the scattering regions are formed as fillets in the intermediate region.

23. The component according to claim 22, wherein the fillets are filled with an adhesion promoter material which is configured to fix the pass-through region to the converter layers.

24. The component according to claim 17, wherein the scattering regions are formed as incisions which are formed as recesses in the pass-through region.

25. The component according to claim 17, wherein the pass-through region is formed by a prefabricated radiation-transmissive and self-supporting body arranged on the converter layers and is spatially spaced from the common carrier.

26. The component according to claim 25, wherein the radiation-transmissive body is fixed to the converter layers by an adhesive layer, and wherein the scattering regions are filled by materials of the adhesive layer.

27. The component according to claim 17, wherein the pass-through region is a platelet and has a rear side facing away from the radiation exit surface, wherein the radiation exit surface is a front side of the pass-through region facing away from the converter layers, and wherein the rear side runs parallel to the front side.

28. The component according to claim 17, wherein the pass-through region is a radiation-transmissive body having oblique side surfaces, and wherein the radiation exit surface has a smaller area than the opposite rear side of the radiation-transmissive body.

29. The component according to claim 17, wherein the pass-through region and the component parts are enclosed in lateral directions by a mold body, and wherein the radiation exit surface is free of a material of the mold body.

30. The component according to claim 29, wherein the mold body contains radiation-scattering and/or radiation-reflecting particles.

31. The component according to claim 17, wherein the pass-through region is formed as part of a mold body, wherein in top view, the mold body completely covers the component parts and in lateral directions, completely encloses the component parts.

32. The component according to claim 17,
wherein the common carrier is configured to mechanically stabilize the component and at the same time to electrically contact the component parts,
wherein each component part has a rear side facing the common carrier and comprises electrical connection points, and
wherein the component parts are electrically conductively connected to the common carrier exclusively via their rear sides.

33. A component comprising:
a common carrier;
a plurality of component parts;
converter layers; and
internal scattering regions,
wherein the component parts are arranged side by side in a lateral direction and vertically between the common carrier and the converter layers,
wherein the component has a pass-through region and a radiation exit surface which, in a vertical direction, is spaced apart from the converter layers by the pass-through region,
wherein adjacent converter layers are laterally spaced from each other by an intermediate region which, in top view of the carrier, is completely covered by the pass-through region,
wherein the inner scattering regions adjoin the pass-through region and the converter layers, and are arranged at least partially in the intermediate region or directly adjoin the intermediate region, and
wherein the inner scattering regions are formed as incisions which are formed as recesses in the pass-through region.

34. A component comprising:
a common carrier;
a plurality of component parts;
converter layers; and
internal scattering regions,
wherein the component parts are arranged side by side in a lateral direction and vertically between the common carrier and the converter layers,
wherein the component has a pass-through region and a radiation exit surface which, in a vertical direction, is spaced apart from the converter layers by the pass-through region,
wherein adjacent converter layers are laterally spaced from each other by an intermediate region which, in top view of the carrier, is completely covered by the pass-through region,
wherein the inner scattering regions adjoin the pass-through region and the converter layers, and are arranged at least partially in the intermediate region or directly adjoin the intermediate region,
wherein the pass-through region is formed as part of a mold body, and
wherein in top view, the mold body completely covers the component parts and in lateral directions, completely encloses the component parts.
